(19) United States
(12) Patent Application Publication
(10) Pub. No.: US 2026/0050700 A1
(43) Pub. Date: Feb. 19, 2026

(54) ENTERPRISE DIGITAL MOCK-UP

(71) Applicant: Textron Innovations Inc., Providence, RI (US)

(72) Inventors: Peter Shultz, Hurst, TX (US); Eric Bush, Arlington, TX (US); Jim Lin, Irving, TX (US); Tom Schneider, Flower Mound, TX (US); Jeremy Chavez, Colleyville, TX (US)

(21) Appl. No.: 18/806,550

(22) Filed: Aug. 15, 2024

(51) Int. Cl. G06F 30/12

(52) U.S. Cl. CPC G06F 30/12

(57) ABSTRACT

A system for providing an enterprise digital mock-up (EDMU) includes one or more first system elements that perform identifying one or more relevant computer aided design (CAD) features of a CAD digital mock-up (DMU), accessing one or more CAD DMUs that are in a first data format and that have at least a portion of the relevant CAD features, and generating, according to the one or more CAD DMUs, an EDMU model in a second data format. The EDMU model in the second data format has a smaller data footprint than the CAD DMUs and omits at least a portion of data of the one or more CAD DMUs. The system further has one or more second system elements that access the EDMU model, display a representation of at least a portion the EDMU model to a user, and display EDMU metadata to the user.

### TECHNICAL FIELD

The present invention relates generally to a system and method for generating and presenting digital mock-ups (DMUs) of computer added design (CAD) models and, in particular embodiments, to a system and method for generating an enterprise digital mock-up (EDMU) model that is a lightweight representation of the design from the CAD DMU and that is presentable in a simple interface with linked metadata providing multi-functional, enterprise-level information on elements of the DMU model.

### BACKGROUND

Generally, design and engineering of large physical objects is performed digitally, with designers and engineers working in a CAD system to define the physical design of machinery, systems, device, circuits and the like. However, CAD systems use powerful, precise software that requires significant computing resources to present graphic representations of the CAD DMU or CAD model. The use of these complex CAD DMUs presents several challenges for downstream consumers of the data, such as manufacturing, supply chain, and support functions. Additionally, digital files for CAD models can be relatively large, making them difficult to transfer, handle, open and otherwise use or manage. CAD models are also often organized and optimized for engineering design purposes, making it difficult for other users to find and extract the specific information they need.

CAD model data and systems are typically siloed and disconnected from other enterprise data sources that are critical for the full product lifecycle, such as manufacturing process planning, supply chain management, in-service support, and other processes. This lack of integration makes it difficult to get a complete, up-to-date view of the product definition and share information effectively across different functions.

Two dimensional (2D) engineering drawings or lightweight three dimensional (3D) view-only formats derived from the CAD DMUs have significant limitations. 2D drawings are static and difficult to keep in sync with the constantly evolving 3D design. They also lack the rich metadata and interactivity of the 3D model. Lightweight 3D formats, while more accessible, often strip out important product structure and metadata in the conversion process.

### SUMMARY

An embodiment system, includes one or more first system elements, including one or more first processors, and at least one first non-transitory computer readable memory connected to the one or more first processors and including first computer program code, where the at least one first non-transitory computer readable memory and the first computer program code are configured, with the one or more first processors, to cause the one or more first system elements to perform at least identifying one or more relevant computer aided design (CAD) features of a CAD digital mock-up (DMU), accessing one or more CAD DMUs that are in a first data format and that have at least a portion of the relevant CAD features, and generating, according to the one or more CAD DMUs, an enterprise digital mock-up (EDMU) model in a second data format, where the EDMU model in the second data format has a smaller data footprint than the one or more CAD DMUs in the first data format, where the EDMU model is associated with EDMU metadata from one or more secondary sources outside of the one or more CAD DMUs, where the EDMU model includes digital representations of at least the relevant CAD features, and where the EDMU model omits at least a portion of data of the one or more CAD DMUs. The system further includes one or more second system elements, including one or more second processors, and at least one second non-transitory computer readable memory connected to the one or more second processors and including second computer program code, where the at least one second non-transitory computer readable memory and the second computer program code are configured, with the one or more second processors, to cause the one or more second system elements to perform at least accessing the EDMU model, displaying a representation of at least a portion the EDMU model to a user, and displaying at least a portion of the EDMU metadata to the user.

An embodiment system includes one or more first processors, and at least one first non-transitory computer readable memory connected to the one or more first processors and including first computer program code, where the at least one first non-transitory computer readable memory and the first computer program code are configured, with the one or more first processors, to cause the system to perform at least identifying one or more relevant computer aided design (CAD) features of a CAD digital mock-up (DMU), accessing the CAD DMU, wherein the CAD DMU is in a first data format and has at least a portion of the relevant CAD features, generating, according to the one or more CAD DMUs, a digital mock-up (EDMU) model in a second data format and having at least a portion of the relevant CAD features, where the EDMU model in the second data format has a smaller data footprint than the CAD DMU in the first data format, where the EDMU model is associated with EDMU metadata from one or more secondary sources outside of the CAD DMU, and where the EDMU model omits at least a portion of data of the CAD DMU, and providing the EDMU model to an EDMU system for display, to a user, of a 3D model represented by at least a portion the EDMU model and of at least a portion of the EDMU metadata associated with the EDMU model.

An embodiment method includes accessing a computer aided design (CAD) model, wherein the CAD digital mock-up (DMU) is in a first data format and has one or more relevant CAD features, generating, according to the CAD DMU, a digital mock-up (EDMU) model in a second data format and having the one or more relevant CAD features, where the EDMU model in the second data format has a smaller data footprint than the CAD DMU in the first data format, and where the EDMU model omits at least a portion of data of the CAD DMU, associating, EDMU metadata from one or more secondary sources outside of the CAD DMU with at least one element of the EDMU model, and providing the EDMU model to an EDMU system for display, to a user, of a 3D model represented by at least a portion the EDMU model and of at least a portion of the EDMU metadata associated with the EDMU model.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is a logical diagram illustrating an EDMU generation and access system according to some embodiments;

FIG. 2 is a logical diagram illustrating a relation between CAD DMU data and EDMU data according to some embodiments;

FIG. 3 is a logical diagram illustrating an EDMU access and generation system according to some embodiments;

FIG. 4 is a logical diagram illustrating a relation between CAD revisions and EDMU models according to some embodiments; and

FIG. 5 is a flow diagram illustrating a method for generating of EDMU models according to some embodiments.

### DETAILED DESCRIPTION OF ILLUSTRATIVE EMBODIMENTS

Embodiments of the principles presented herein provide for an enterprise digital mock-up (EDMU) that is lightweight and accessible using relatively simple software, but that includes metadata and information derived from sources outside of the CAD system.

The EDMU system disclosed herein provides downstream users with easy, interactive access to the 3D product definition, including both the geometry and the associated metadata, without requiring CAD software or specialized training. The 3D data is, in some embodiments, integrated with data from other secondary or supplemental enterprise data sources and processes to support the full product lifecycle. Additionally, the EDMU system is arranged to handle the scale and complexity of modern engineering programs for large scale projects, which can involve millions of parts and constant engineering changes.

The presented system and method provide for a novel EDMU system that extracts and reconciles 3D product data from authoritative CAD systems, integrates it with metadata from other secondary or supplemental enterprise sources, and provides a lightweight, user-friendly interface for interacting with and consuming the data across the organization.

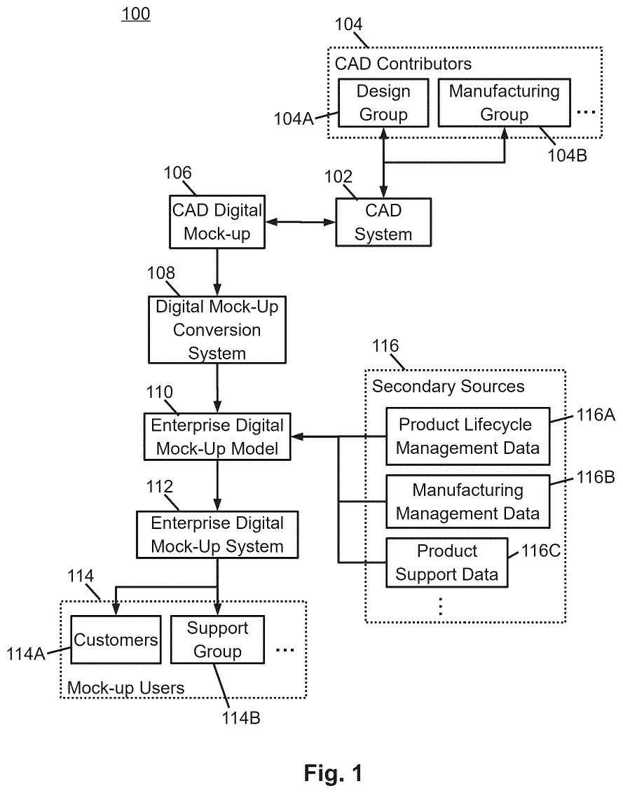

FIG. 1 is a logical diagram illustrating an EDMU generation and access system 100 according to some embodiments. The system 100 may have a CAD system 102 accessed by one or more CAD contributors 104. In some embodiments, CAD contributors 104 such as personnel from a design group 104A, manufacturing group 104B, or the like, may access the CAD system 102 to make changes, provide designs or submissions for a project or provide data for a project that is used with, or integrated into a CAD DMU 106. The CAD system 102 allows editing or access to the CAD DMU 106 so that CAD contributors 104 may access or work on the CAD DMU 106 while EDMU models 110 are generated to create working snapshots of a particular stage in a project, or prototype or non-finalized parts or arrangements, and the like. This permits separation of the CAD DMU 106 and an EDMU model 110.

In some embodiments, a DMU conversion system 108 accesses the CAD DMU 106 to generate the EDMU model 110. The DMU conversion system 108 may be a system that is separate from the CAD system 102, which may permit generation of the EDMU model 110 separately from operation of the CAD system 102. In other embodiments, the DMU conversion system 108 may be integrated into the CAD system 102, so that EDMU model generation is triggered by a user of the CAD system 102, by an automated system, or the like. In another embodiment, the DMU conversion system 108 may be part of a version control system, or the like, and may be automatically initiated to generate the EDMU model 110. For example, the DMU conversion system 108 may be a standalone computing system that accesses a storage device storing the CAD DMU 106, and that loads a CAD model, or at least the relevant CAD DMU data, for generation of the EDMU model 110. The EDMU model 110 may be generated as a result of a predetermined trigger, such as expiration of a timer, a particular time being reached, submission of a predetermined number of changes, submission of a change to a particular element or part of the CAD model, a manual indication by a user or system to generate the EDMU model 110, or the like.

In some embodiments, the DMU conversion system 108 loads relevant parts of the CAD DMU 106 and generates the EDMU model 110 from the CAD DMU 106. The EDMU model 110 may be in a different format than the CAD DMU 106, and may be simpler, smaller, less precise, or otherwise be more lightweight, with a smaller data footprint, than the CAD DMU 106. For example, the CAD DMU 106 may be represented by data in one or more DWG files, DXF files, 3DXML, or files in another native 3D CAD file format. The DMU conversion system 108 may convert at least a portion of the CAD DMU 106 into the EDMU model in another data or file format. For example, the EDMU model 110 may be represented by data in one or more 3D modelling formats or files, such as FBX files, DAE files, OBJ files, or the like, which may use a data format different than the format used by the CAD system to display the 3D CAD model. Thus, the DMU conversion system 108 may convert the 3D CAD model that is in the first 3D format into the EDMU model in the second 3D format. Converting between formats may comprise removing engineering or display specific data, or removing other data that is non-3D display data. In some embodiments, the DMU conversion system may load a limited representation of the CAD DMU 106, and may render the CAD DMU data as an EDMU model 110 in a suitable format, convert the CAD DMU data to a format associated with the EDMU model 110, or otherwise use the CAD DMU data to generate the EDMU model. In some embodiments, the DMU conversion system 108 may use part of the CAD DMU data in the EDMU model 110, but may omit, truncate, adjust, modify or otherwise change the data in the CAD DMU 106 to generate the EDMU model 110. For example, the DMU conversion system may use the 3D representational data from the CAD DMU 106, but may remove engineering data, remove display-specific data such reference datums, tooling surfaces, reference structure backgrounds, duplicate textures, previous revisions, and the like, that may be stored as part of the CAD DMU. For example, the CAD DMU or CAD model may be displayed as a representation in a CAD system, or using a CAD file format, and a graphics system may use the data loaded for display to determine a new 3D representation with a smaller data footprint, for example, by rendering external or required faces of the 3D model, by re-rendering the CAD DMU as a polygonal model rather than a boundary representation (b-Rep) model, without raytracing, without complex textures, or lighting, and the like. In another example, the DMU conversion system 108 may re-render the CAD DMU in a lower resolution, such as with a higher polygon count, or with a less precise drawing output to simplify the EDMU model. In yet another example, the DMU conversion system 108 may load a data file holding the CAD DMU, and may use the data in the file for the conversion process without rendering the CAD DMU, either visually or internally. Thus, the EDMU model may include part of the 3D modelling data from the CAD DMU, but may have less data than the CAD DMU 106 in order to reduce the complexity and size of the EDMU model and associated files. In another embodiment, the DMU conversion system may convert a portion of the CAD DMU 106 to the EDMU model by rendering or converting 3D model data in the CAD DMU 106 into a different representation, file format, structure or rendering format. The conversion process may involve only converting a portion of the CAD DMU 106, so that at least a part of the data from CAD DMU 106 is omitted from the EDMU model 110. Thus, the EDMU model is lighter in weight, and less complex, than the CAD DMU 106.

Additionally, in some embodiments, the EDMU model 110 includes, or is associated with, data from or more secondary sources 116. The secondary sources 116 may be sources of data such as product lifecycle management data 116A, manufacturing management data 116B, product support data 116C, or the like. The secondary sources 116 may be separate from the CAD system 102 and include data that is managed or stored separately from the CAD DMU 106 data, permitting the EDMU model 110 to include or be associated with data outside of the CAD DMU environment. In some embodiments, the data from the secondary sources 116 is metadata associated with the EDMU model 110, or with elements of the EDMU model, and may be included in the EDMU model 110. In other embodiments, the EDMU model 110, or elements of the EDMU model 110, may be tagged or have an identifier that permits linking metadata from one or more secondary sources 116, so that the metadata may be accessed or available when a mock-up user 114 accesses the EDMU model 110. Thus, the EDMU model 110 may comprise metadata that is stored in the EDMU model 110 itself, or that is stored remotely.

The EDMU model 110 may be generated to display a 3D model in “fly-away” condition, where a representation of a usable vehicle, system, machine, or the like, is available for display outside of a CAD environment by multiple parties, so that the different parties or groups may collaborate and reference a common model in lightweight form, and with secondary data that supplements the 3D representation.

In some embodiments, the EDMU model 110 may be loaded or accessed by a digital mock-up system 112 for display to one or more mock-up users 114. The mock-up users 114 may include one or more users that are customers 114A, support group 114B users, engineers, sales people, technical writes, analysts, and the like, and that view or access the EDMU model 110 through a user interface provided by the EDMU system 112. The EDMU system 112 may be a standalone system configured to display the EDMU model without requiring specialized training or large scale CAD modelling software associated with the CAD DMU 106. For example, the EDMU system 112 may be a display program using, for example, a display engine such as the Unreal engine, Unity® engine, CryEngine® or any other 3D display program. In other embodiments, the EDMU system may be native display software implementing 32D display libraries such as DirectX®, OpenGL®, Vulcan®, or the like. The EDMU system 112 may be configured to display selected portions or subsystems of the EDMU model to permit mock-up users 114 to select specific subsystems, elements, or the like for analysis.

Each CAD system 102, EDMU conversion system 108, EDMU system, and storage for the CAD DMU 106 and EDMU model 110 may be a system component that is implemented separately from other system components, or one or more of those system components may be hosted on a same server or computer system. For example, the CAD system 102 and EDMU conversion system 108 may be hosted on the same hardware, with the CAD system 102 and EDMU conversion system 108 being implemented by separate software or processes. In such an example, the EDMU system 112 may be software running on hardware separate from the EDMU conversion system 108 and CAD system 102 to permit mock-up users 114 to remotely access the EDMU model 110.

Each system component may include one or more processors and one or more computer readable medium storing computer code thereon. References to computer-readable storage medium, computer program product, tangibly embodied computer program, or the like, or a controller, monitor, engine monitor, monitoring system, computer, processor, or the like should be understood to encompass not only computers having different architectures such as single or multi-processor architectures and sequential (Von Neumann) or parallel architectures but also specialized circuits such as field-programmable gate arrays (FPGAs), application specific circuits (ASICs), signal processing devices and other devices. References to computer program, instructions, code, or the like, should be understood to encompass software for a programmable processor or firmware such as, for example, the programmable content of a hardware device whether instructions for a processor, or configuration settings for a fixed-function device, gate array or programmable logic device, or the like.

Each system component may have at least one processor and at least one memory, such as a non-transitory computer readable medium, and may include computer program code, that is configured to, with the at least one processor, provide the data processing and communication. The memory may be a single component or it may be implemented as one or more separate components some or all of which may be integrated or removable and may provide permanent, semi-permanent, dynamic, or cached storage.

The one or more processors are configured to read from and write to the at least one memory. The processor may also comprise an output interface via which data or commands are output by the processor and an input interface via which data or commands are input to the processor. The memory stores a computer program including computer program instructions that control the operation of the engine monitoring, and possibly the overall system, when loaded into the processor. The computer program instructions provide the logic and routines that enable the apparatus to perform the data processing and communication and implement the various systems. The processor, by reading the memory, is able to load and execute the computer program. The computer program or programs may arrive at the apparatus via any suitable delivery mechanism. The delivery mechanism may be, for example, a computer-readable storage medium, a computer program product, a memory device, a record medium such as a compact disc read on only memory (CD-ROM), digital versatile disc (DVD), portable memory such as a memory stick or hard drive, or the like, an article of manufacture that tangibly embodies the computer program. In some embodiments, the delivery mechanism may be a signal configured to reliably transfer the computer program over the air or via an electrical connection.

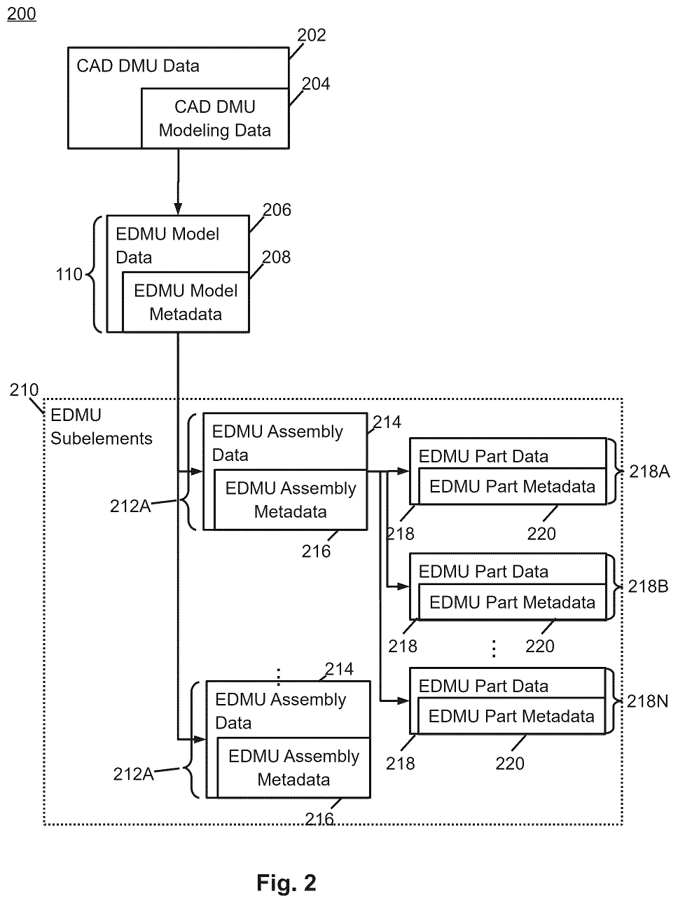

FIG. 2 is a logical diagram illustrating a relation 200 between CAD data and EDMU data according to some embodiments. In some embodiments, a CAD DMU includes CAD DMU data 202 and CAD DMU modelling data 204. The CAD DMU modelling data 204 is a subsection of the CAD DMU data 202, and may include data describing the 3D model. The remainder of the CAD DMU data 202 may include the remainder of the CAD data that is not the modeling data. In some embodiments, the remainder of the CAD DMU data 202 may include support data for the CAD DMU modeling data 204, format and layout data, and the like. For example, a DXF file may include information for application defined classes, style and property definitions, paperspace layout, graphical entities, non-graphical objects, and additional support data, where the graphical entities include the CAD DMU modeling data 204.

An EDMU model 110 may include EDMU model data 206, and EDMU model metadata 208. The EDMU model data 206 may include data representing at least a portion of the 3D model being converted into the EDMU model 110 from the CAD DMU. The EDMU model metadata 208 may include data from sources other than the CAD DMU data, or may include non-modeling data from the EDMU model. For example, in some embodiments, the EDMU model metadata 208 may include production data such as a bill of materials, an identifier used to link outside data to the EDMU model 110, data for support issues, such as help files, technical bulletins, or the like, or may include other supplemental or secondary data.

One or more EDMU subelements 210 may be associated with, or included in, the EDMU model 110. The EDMU subelements 210 may form a hierarchical arrangement of portions or elements of the EDMU model 110 to permit organization and management of pieces of the EDMU model 110, and may be groups or elements that make up an overall EDMU model 110, and may be individually identified so that user can perform filtering on parts, assemblies or the like. For example, the EDMU model 110 may include EDMU subelements 210 that are EDMU assemblies 212A . . . 212N or EDMU parts 218A . . . 218N, or the EDMU parts 218A . . . 218N may be associated with EDMU assemblies 212A . . . 212N. For example, a vehicle EDMU model may have an EDMU assembly 212A . . . 212N for a chassis, another EDMU assembly 212A . . . 212N for a body, and an EDMU assembly 212A . . . 212N for a power train. The EDMU assembly 212A . . . 212N for the body may have EDMU parts 218A . . . 2a8N for various panels and associated features that form the body EDMU assembly 212A . . . 212Ns. Each of the panels may be a separate EDMU part with their own, respective, EDMU part data 218 and EDMU part metadata 220. The EDMU part data 218 may include data that describes the 3D features of the respective part, and may be used for a visual display, and the EDMU part metadata 220 may be secondary or supplemental data associated with the EDMU part 218A . . . 218N.

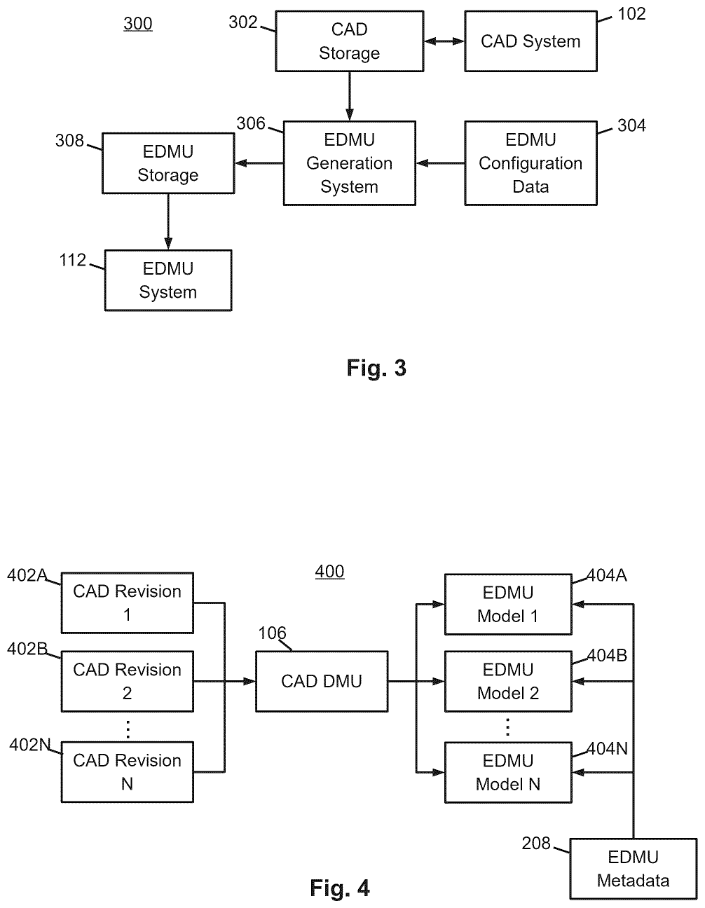

FIG. 3 is a logical diagram illustrating an EDMU access and generation system 300 according to some embodiments. The CAD system 102 communicates with a CAD storage system 302, and the CAD system may load and save CAD DMU data in a centralized storage system provided by the CAD storage system 302. In some embodiments, the CAD storage system 302 is a file server, database, file management system, version control system, or other software, hardware, or combination thereof configured for data storage. The CAD system 102 permits users to access CAD data stored in the CAD storage system 302, and to view, modify, or otherwise interact with the CAD data.

The EDMU generation system 306 may access the CAD storage system 302 to load selected CAD data, and to generate EDMU models, EDMU data, or the like. The EDMU generation system may access EDMU configuration data 304 that indicates which parts of a CAD DMU are included in a generated EDMU model. In some embodiments, the EDMU configuration data 304 may be stored as one or more preset or predetermined options or commands, and may be stored in, for example, an EDMU storage system 308, or in anther storage location. For example, EDMU model generation may be performed by an automated system that runs at a predetermined interval, such as daily, to generate an EDMU model with any changes made during the previous day so that users outside of the CAD system may have access to current engineering specifications. The automated system may load the EDMU configuration data to determine what elements of the CAD DMU should be used in the EDMU model, and in some embodiments, to determine what data should be used from secondary sources to provide the EDMU metadata, EDMU assembly metadata, or EDMU part metadata for a newly generated EDMU model. For example, the EDMU generation system 306 may implement and automated EDMU generation process that loads the EDMU configuration data 304, which indicates to generate a first EDMU model using, for example, airframe and body panel CAD data, and to generate a second EDMU model using, for example, airframe, drive systems, and fuel system CAD data. The configuration data may further indicate different metadata to be generated for the first and second EDMU models. Thus, customized, lightweight models may be generated for particular groups, or to reduce the complexity of the models to simplify access to the 3D structures that were originally stored in the CAD DMUS.

In other embodiments, the EDMU configuration data 304 may be provided by a user, automated system, or other source. For example, a user that needs to generate a custom or current EDMU model may access the EDMU generation system 306, and start an EDMU generation process by giving commands to the EDMU generation system 306, along with one or more configurations for the EDMU model to be generated. For example, a salesperson may wish to provide an EDMU model reflecting a customized machine ordered by a customer, and may command the EDMU generation system 306 to generate an EDMU model from the current CAD DMU in the CAD storage system 302, and may provide EDMU configuration data 304 indicating to include customer selected graphics or skins on the EDMU model, while omitting interior or hidden parts to further reduce the size and complexity of the file for the EDMU model.

The EDMU generation system 306 may store generated EDMU models in the EDMU storage system 308. In some embodiments, the EDMU model may include direct storage of the EDMU model metadata, and in other embodiments, the EDMU model may include an identifier that is treated as metadata and that is used to associate the external data with the EDMU model. Thus, the EDMU storage system 308 may store generated EDMU models with related secondary information such as EDMU model metadata, relationships between EDMU models, EDMU parts, EDMU assemblies and EDMU metadata, EDMU metadata or model identifiers, or any other data related to the EDMU model.

Users may use the EDMU system 112 to access an EDMU model stored on the EDMU storage system 308. The EDMU system may include an interface that permits a user to view the EDMU model by rendering the EDMU model according to data stored in the EDMU model storage 308. Additionally, the EDMU system 112 may provide an interface for viewing supplements data such as metadata. In systems where the metadata is stored in the EDMU storage, or is stored in part of the EDMU model, the EDMU system may load the EDMU metadata from the EDMU storage system 308. In embodiments where the metadata is maintained outside the EDMU system, for example, in a secondary source, or in another database or storage separate from the EDMU storage system 308, the EDMU system 112 may use identifying information in the EDMU model, or in the EDMU configuration data 304, to retrieve the EDMU metadata, as needed. For example, where a user has loaded an EDMU model and is viewing the referenced representation of a 3D structure provided by the EDMU model, the user may select a part of an assembly in the EDMU system 112 interface, and the EDMU system may determine the EDMU element or subelement that is the subject of focus in the interface. The EDMU system 112 may then retrieve the required or associated metadata for display to the user. The metadata may be retrieved by the EDMU system from a secondary source based on the EDMU element or subelement that is selected or is the subject of focus.

In another embodiment, the EDMU system 112 may load metadata from a secondary source for all elements of a loaded EDMU model prior to a user selecting any particular EDMU model element, which may reduce the delay in showing the metadata when the user interacts with the EDMU model.

FIG. 4 is a logical diagram illustrating a relation between CAD revisions 402A . . . 402N and EDMU models 404A . . . 404N according to some embodiments. Users may make changes to a CAD DMU 106 by submitting a new CAD revision 402A . . . 402N to, for example, a CAD system that integrates changes into a CAD DMU 106 stored in, for example, a CAD storage system. Different users may submit different CAD revisions 402A . . . 402N, and multiple users may work on different parts of the CAD DMU 106 at the same time by submitting CAD revisions 402A . . . 402N on different parts, assemblies, or sections of the CAD DMU 106. Multiple EDMU models 404A . . . 404N may be generated from the CAD DMU 106. In some embodiments, different EDMU models 404A . . . 404N are generated at different times, to keep the most current EDMU model tracing changes to the CAD DMU 106 as the changes are made. Thus, for example, a system that generates a new EDMU model daily would have changes made during a workday reflected in a new EDMU model 404A . . . 404N. In some embodiments, the EDMU models may be generated on demand in response to a particular CAD revision to provide an EDMU model of a particular revision, part, assembly, or the like that may be a prototype, and not formally incorporated into the CAD DMU. The specific revision may be rolled back, changed, revised, or the like, after generation of the EDMU model 404A . . . 404N. For example, a vehicle with particular body options may be modelled by submitting a CAD revision 402A . . . 402N used in the CAD DMU 106, and an EDMU model 404A . . . 404N generated for display to a customer, designer, or the like. Rejection of the body options may result in the CAD revision being rolled back or removed from the CAD DMU 106, and a new EDMU model 404A . . . 404C generated without the rejected CAD revision 402A . . . 404N.

EDMU model metadata 208 may persist across multiple EDMU models 404A . . . 404N. For example, the same EDMU model metadata 208 may be used for like parts in different EDMU models 404A . . . 404N. In some embodiments, like parts used across different EDMU models 404A . . . 404N may use a same identifier, and particular pieces of EDMU model metadata 208 may be the same because it is associated with the same identifier, and thus, with the same part.

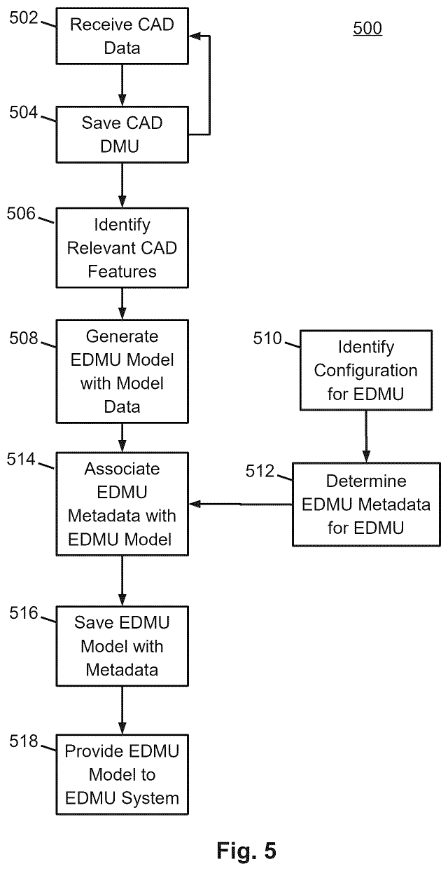

FIG. 5 is a flow diagram illustrating a method 500 for generating of EDMU models according to some embodiments. In block 502, CAD data is received. The CAD data may be a new design, a preexisting design, a CAD revision, or any other CAD data. In block 504, a CAD DMU is saved. The CAD DMU may be a CAD model, an assembly, part, or the like. Saving the CAD DMU may, in some embodiments, include saving revisions to an existing CAD DMU or CAD model, saving a new CAD DMU or CAD model, or the like. In some embodiments, the process of receiving CAD data and saving the CAD DMU or CAD model can be repeated any number of times to permit changes to a CAD DMU or CAD model and an iterative design process.

In block 506, one or more relevant CAD features are identified. The identified CAD features may include features from a particular CAD DMU or CAD model that may be included in an EDMU model. In some embodiments, a subsystem, assembly, or the like may be selected from a CAD DMU for inclusion in the EDMU model, and some parts of the CAD DMU may be omitted for clarity, where not necessary for the intended recipients of the EDMU model, or for any other reason. In other embodiments, all parts from a CAD DMU may be identified as being relevant for an EDMU model. The identification of the relevant CAD features may be performed in response to a user input. Thus, in some embodiments, a user may select one or more parts for inclusion in the EDMU model from the CAD DMU in the user interface of the CAD system, by manually starting the EDMU generation process and using one or more parts of a CAD DMU, or the entire CAD DMU, as a default part selection, or the like. In another embodiments, an EDMU system may be set up to include predetermined parts or assemblies in a particular EDMU model generation process. For example, an automated EDMU generation system may generate an EDMU model of a particular subsystem, such as an electrical or fuel management system, at a predetermined time, a predetermined interface, in response to submission of system changes, or the like. The elements included in such an EDMU model may be predetermined, and identified, for example, in EDMU configuration data.

In block 508, an EDMU model is generated with model data. The EDMU generation may include generation of an EDMU for the identified relevant CAD features, and using data from the saved CAD DMU.

In block 510, a configuration is identified, in some embodiments, for the EDMU model. The configuration may be a predetermined configuration, a configuration identified by an automated process, a configuration identified by a user, or the like, a default configuration, or a configuration identified by a combination of sources. The configuration may include EDMU configuration information indicating EDMU metadata, relationships between metadata and EDMU elements, metadata sources, and the like.

In block 512, the EDMU metadata for the EDMU model is determined. The EDMU metadata may be determined according to the configuration for the EDMU, and may include determining metadata intended for inclusion in the EDMU model, or determining what metadata stored in a secondary source, database, or the like, will be linked to the EDMU model.

In block 514, EDMU metadata is associated with the EDMU model. In some embodiments, EDMU metadata is copied into the EDMU model, and in other embodiments, the EDMU metadata is stored separately from the EDMU model, and an identifier or other data linking the EDMU model to the EDMU metadata is used. For example, where the EDMU metadata is copied into the EDMU model, selected parts of the EDMU metadata from a secondary source such as a database, previous EDMU model, file server, user interface, or the like, are copied into the EDMU model in a format readable or usable by the EDMU system. In another example where the EDMU metadata is stored separately from the EDMU model, the system may associate an identifier within the EDMU model with metadata stored in the secondary source, or may store data indicating a location of the EDMU metadata in the EDMU model. In some embodiments, this may include storing, in a second location such as a database, an identifier of an EDMU part, EDMU assembly, EDMU model, or other EDMU element in a database with an associated location for the target EDMU metadata. This may permit an EDMU system to retrieve EDMU metadata for a particular EDMU element from a secondary source when needed, as the EDMU system is able to determine an identifier for a relevant EDMU element from the identifier stored in the EDMU model, and then query the second location for the location data for EDMU metadata associated with the identifier. The EDMU system may then retrieve the EDMU metadata from the secondary source using the location data. In another example, the EDMU generation system may copy the location of the metadata for a particular EDMU element into the data structure for the EDMU element within the EDMU model, so that the EDMU system retrieves the EDMU metadata from a secondary source according to location data stored directly in the EDMU model.

In block 516, the EDMU model with the EDMU metadata set is saved. The EDMU model may be saved in a centrally accessible location, such as a file server, database, or other data repository, or may be distributed to the relevant users, or the like. In block 518, the EDMU model is provided to an EDMU system. The EDMU system may load the EDMU model and relevant metadata for display to a user.

An embodiment system, includes one or more first system elements, including one or more first processors, and at least one first non-transitory computer readable memory connected to the one or more first processors and including first computer program code, where the at least one first non-transitory computer readable memory and the first computer program code are configured, with the one or more first processors, to cause the one or more first system elements to perform at least identifying one or more relevant computer aided design (CAD) features of a CAD digital mock-up (DMU), accessing one or more CAD DMUs that are in a first data format and that have at least a portion of the relevant CAD features, and generating, according to the one or more CAD DMUs, an enterprise digital mock-up (EDMU) model in a second data format, where the EDMU model in the second data format has a smaller data footprint than the one or more CAD DMUs in the first data format, where the EDMU model is associated with EDMU metadata from one or more secondary sources outside of the one or more CAD DMUs, where the EDMU model includes digital representations of at least the relevant CAD features, and where the EDMU model omits at least a portion of data of the one or more CAD DMUs. The system further includes one or more second system elements, including one or more second processors, and at least one second non-transitory computer readable memory connected to the one or more second processors and including second computer program code, where the at least one second non-transitory computer readable memory and the second computer program code are configured, with the one or more second processors, to cause the one or more second system elements to perform at least accessing the EDMU model, displaying a representation of at least a portion the EDMU model to a user, and displaying at least a portion of the EDMU metadata to the user.

In some embodiments, the generating the EDMU model in the second data format includes storing the EDMU metadata from the one or more secondary sources in the EDMU model. In some embodiments, the generating the EDMU model in the second data format includes storing location data of the EDMU metadata in the EDMU model. In some embodiments, the displaying the at least the portion of the EDMU metadata to the user includes retrieving EDMU metadata for an EDMU model element displayed in a user interface of the one or more second system elements from the one or more secondary sources according to the location data and in response to user selecting the EDMU model element. In some embodiments, the generating the EDMU model in the second data format includes storing location data of the EDMU metadata and an association between the EDMU metadata and a portion of the EDMU model in a second location outside the EDMU model. In some embodiments, the generating the EDMU model in the second data format includes storing an identifier of an EDMU model element in the EDMU metadata, and storing the location data of the EDMU metadata and the association between the EDMU metadata and the portion of the EDMU model in the second location includes storing, in the second location, an association between a portion of the EDMU metadata for the EDMU model element and the identifier. In some embodiments, the CAD DMU is at least one of engineering data or display-specific data, and the EDMU model omits the at least one of the engineering data or display-specific data. In some embodiments, the generating the digital mock-up (EDMU) model in a second data format includes converting a 3D CAD model that is in a first 3D format into a 3D EDMU model in a second 3D format.

An embodiment system includes one or more first processors, and at least one first non-transitory computer readable memory connected to the one or more first processors and including first computer program code, where the at least one first non-transitory computer readable memory and the first computer program code are configured, with the one or more first processors, to cause the system to perform at least identifying one or more relevant computer aided design (CAD) features of a CAD digital mock-up (DMU), accessing the CAD DMU, wherein the CAD DMU is in a first data format and has at least a portion of the relevant CAD features, generating, according to the one or more CAD DMUs, a digital mock-up (EDMU) model in a second data format and having at least a portion of the relevant CAD features, where the EDMU model in the second data format has a smaller data footprint than the CAD DMU in the first data format, where the EDMU model is associated with EDMU metadata from one or more secondary sources outside of the CAD DMU, and where the EDMU model omits at least a portion of data of the CAD DMU, and providing the EDMU model to an EDMU system for display, to a user, of a 3D model represented by at least a portion the EDMU model and of at least a portion of the EDMU metadata associated with the EDMU model.

In some embodiments, the providing the EDMU model to the EDMU system causers the EDMU system to perform at least accessing the EDMU model, displaying a representation of at least a portion the EDMU model to the user, and displaying at least a portion of the EDMU metadata to the user. In some embodiments, the generating the EDMU model in the second data format includes storing, in the EDMU model, location data of the EDMU metadata or EDMU metadata from the one or more secondary sources. In some embodiments, the generating the EDMU model in the second data format includes storing location data of the EDMU metadata and an association between the EDMU metadata and a portion of the EDMU model in a second location outside the EDMU model. In some embodiments, the generating the EDMU model in the second data format includes storing an identifier of an EDMU model element in the EDMU metadata, and where storing the location data of the EDMU metadata and the association between the EDMU metadata and the portion of the EDMU model in the second location includes storing, in the second location, an association between a portion of the EDMU metadata for the EDMU model element and the identifier. In some embodiments, the CAD DMU has at least one of engineering data or display-specific data, and the EDMU model omits the at least one of the engineering data or display-specific data. In some embodiments, the generating the EDMU model in a second data format includes converting a 3D CAD DMU that is in a first 3D format into a 3D EDMU model in a second 3D format.

An embodiment method includes accessing a computer aided design (CAD) model, wherein the CAD digital mock-up (DMU) is in a first data format and has one or more relevant CAD features, generating, according to the CAD DMU, a digital mock-up (EDMU) model in a second data format and having the one or more relevant CAD features, where the EDMU model in the second data format has a smaller data footprint than the CAD DMU in the first data format, and where the EDMU model omits at least a portion of data of the CAD DMU, associating, EDMU metadata from one or more secondary sources outside of the CAD DMU with at least one element of the EDMU model, and providing the EDMU model to an EDMU system for display, to a user, of a 3D model represented by at least a portion the EDMU model and of at least a portion of the EDMU metadata associated with the EDMU model.

In some embodiments, the method further includes displaying a representation of at least a portion the EDMU model to the user, and displaying at least a portion of the EDMU metadata to the user. In some embodiments, the generating the EDMU model in the second data format includes storing the EDMU metadata from the one or more secondary sources in the EDMU model. In some embodiments, the CAD DMU has at least one of engineering data or display-specific data, and the EDMU model omits the at least one of the engineering data or display-specific data. In some embodiments, the generating the EDMU model in a second data format includes converting a 3D CAD DMU that is in a first 3D format into a 3D EDMU model in a second 3D format.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments

What is claimed is:

1. A system, comprising:
one or more first system elements, comprising:
one or more first processors; and
at least one first non-transitory computer readable memory connected to the one or more first processors and including first computer program code, wherein the at least one first non-transitory computer readable memory and the first computer program code are configured, with the one or more first processors, to cause the one or more first system elements to perform at least:
identifying one or more relevant computer aided design (CAD) features of a CAD digital mock-up (DMU);
accessing one or more CAD DMUs that are in a first data format and that have at least a portion of the relevant CAD features; and
generating, according to the one or more CAD DMUs, an enterprise digital mock-up (EDMU) model in a second data format, wherein the EDMU model in the second data format has a smaller data footprint than the one or more CAD DMUs in the first data format, wherein the EDMU model is associated with EDMU metadata from one or more secondary sources outside of the one or more CAD DMUs, wherein the EDMU model comprises digital representations of at least the relevant CAD features, and wherein the EDMU model omits at least a portion of data of the one or more CAD DMUs; and
one or more second system elements, comprising:
one or more second processors; and
at least one second non-transitory computer readable memory connected to the one or more second processors and including second computer program code, wherein the at least one second non-transitory computer readable memory and the second computer program code are configured, with the one or more second processors, to cause the one or more second system elements to perform at least:
accessing the EDMU model;
displaying a representation of at least a portion the EDMU model to a user; and
displaying at least a portion of the EDMU metadata to the user.

2. The system of claim 1, wherein the generating the EDMU model in the second data format comprises storing the EDMU metadata from the one or more secondary sources in the EDMU model.

3. The system of claim 1, wherein the generating the EDMU model in the second data format comprises storing location data of the EDMU metadata in the EDMU model.

4. The system of claim 3, wherein the displaying the at least the portion of the EDMU metadata to the user comprises retrieving EDMU metadata for an EDMU model element displayed in a user interface of the one or more second system elements from the one or more secondary sources according to the location data and in response to user selecting the EDMU model element.

5. The system of claim 1, wherein the generating the EDMU model in the second data format comprises storing location data of the EDMU metadata and an association between the EDMU metadata and a portion of the EDMU model in a second location outside the EDMU model.

6. The system of claim 5, wherein the generating the EDMU model in the second data format comprises storing an identifier of an EDMU model element in the EDMU metadata; and
wherein storing the location data of the EDMU metadata and the association between the EDMU metadata and the portion of the EDMU model in the second location comprises storing, in the second location, an association between a portion of the EDMU metadata for the EDMU model element and the identifier.

7. The system of claim 1, wherein the CAD DMU comprises at least one of engineering data or display-specific data, and wherein the EDMU model omits the at least one of the engineering data or display-specific data.

8. The system of claim 1, wherein the generating the digital mock-up (EDMU) model in a second data format comprises converting a 3D CAD model that is in a first 3D format into a 3D EDMU model in a second 3D format.

9. A system, comprising:
one or more first processors; and
at least one first non-transitory computer readable memory connected to the one or more first processors and including first computer program code, wherein the at least one first non-transitory computer readable memory and the first computer program code are configured, with the one or more first processors, to cause the system to perform at least:
identifying one or more relevant computer aided design (CAD) features of a CAD digital mock-up (DMU);
accessing the CAD DMU, wherein the CAD DMU is in a first data format and has at least a portion of the relevant CAD features;
generating, according to the one or more CAD DMUs, a digital mock-up (EDMU) model in a second data format and having at least a portion of the relevant CAD features, wherein the EDMU model in the second data format has a smaller data footprint than the CAD DMU in the first data format, wherein the EDMU model is associated with EDMU metadata from one or more secondary sources outside of the CAD DMU, and wherein the EDMU model omits at least a portion of data of the CAD DMU; and
providing the EDMU model to an EDMU system for display, to a user, of a 3D model represented by at least a portion the EDMU model and of at least a portion of the EDMU metadata associated with the EDMU model.

10. The system of claim 9, wherein the providing the EDMU model to the EDMU system causers the EDMU system to perform at least:
accessing the EDMU model;
displaying a representation of at least a portion the EDMU model to the user; and
displaying at least a portion of the EDMU metadata to the user.

11. The system of claim 9, wherein the generating the EDMU model in the second data format comprises storing, in the EDMU model, location data of the EDMU metadata or EDMU metadata from the one or more secondary sources.

12. The system of claim 9, wherein the generating the EDMU model in the second data format comprises storing location data of the EDMU metadata and an association between the EDMU metadata and a portion of the EDMU model in a second location outside the EDMU model.

13. The system of claim 12, wherein the generating the EDMU model in the second data format comprises storing an identifier of an EDMU model element in the EDMU metadata; and
wherein storing the location data of the EDMU metadata and the association between the EDMU metadata and the portion of the EDMU model in the second location comprises storing, in the second location, an association between a portion of the EDMU metadata for the EDMU model element and the identifier.

14. The system of claim 9, wherein the CAD DMU comprises at least one of engineering data or display-specific data, and wherein the EDMU model omits the at least one of the engineering data or display-specific data.

15. The system of claim 9, wherein the generating the EDMU model in a second data format comprises converting a 3D CAD DMU that is in a first 3D format into a 3D EDMU model in a second 3D format.

16. A method, comprising:
accessing a computer aided design (CAD) model, wherein the CAD digital mock-up (DMU) is in a first data format and has one or more relevant CAD features;
generating, according to the CAD DMU, a digital mock-up (EDMU) model in a second data format and having the one or more relevant CAD features, wherein the EDMU model in the second data format has a smaller data footprint than the CAD DMU in the first data format, and wherein the EDMU model omits at least a portion of data of the CAD DMU;
associating EDMU metadata from one or more secondary sources outside of the CAD DMU with at least one element of the EDMU model; and
providing the EDMU model to an EDMU system for display, to a user, of a 3D model represented by at least a portion the EDMU model and of at least a portion of the EDMU metadata associated with the EDMU model.

17. The method of claim 16, further comprising:
displaying a representation of at least a portion the EDMU model to the user; and
displaying at least a portion of the EDMU metadata to the user.

18. The method of claim 16, wherein the generating the EDMU model in the second data format comprises storing the EDMU metadata from the one or more secondary sources in the EDMU model.

19. The method of claim 16, wherein the CAD DMU comprises at least one of engineering data or display-specific data, and wherein the EDMU model omits the at least one of the engineering data or display-specific data.

20. The method of claim 16, wherein the generating the EDMU model in a second data format comprises converting a 3D CAD DMU that is in a first 3D format into a 3D EDMU model in a second 3D format.
